(19) United States
(12) Patent Application Publication
(10) Pub. No.: US 2003/0197665 A1
(43) Pub. Date: Oct. 23, 2003

(54) Driving circuit design for display device

(76) Inventor: Chih-Feng Sung, Miao-Li Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,647

(22) Filed: Nov. 6, 2002

(30) Foreign Application Priority Data
Apr. 17, 2002 (TW) 91107826

(51) Int. Cl. G09G 3/32; G09G 5/00

(52) U.S. Cl. 345/82; 345/204; 345/83

(57) ABSTRACT

A driving circuit design for a display device. This invention uses the voltage-driven circuit of a conventional TFT-LCD such that the pixel is capable of outputting a different driving current to each OLED having a characteristic red, green or blue coloration under identical data voltage conditions. Different driving currents are produced by adjusting channel width/length ratio of the TFT driver in each pixel. Consequently, an appropriate luminance ratio between red, green and blue lights may be set to reproduce white light through the red, green and blue OLED and hence attain full coloration.

### CROSS REFERENCE TO RELATED APPLICATIONS

This application claims the priority benefit of Taiwan application serial no. 91107826, filed Apr. 17, 2002.

### BACKGROUND OF INVENTION

1. Field of Invention

The present invention relates to the driving circuit of a display device. More particularly, the present invention relates to a voltage-driven circuit design for a display device.

1. Description of Related Art

Dynamic recording of documentary through film has a long history. With the invention of cathode ray tube (CTR) and broadcasting equipment, television has become an indispensable electronic device in almost every family. Due to rapid progress in the electronic industry, CRTs are also used as monitors for desktop computers. However, the CRT is now gradually being phased out due to radiation hazards and the bulkiness of the CRT body that needs to house an electron gun.

Because of radiation hazards and bulkiness, flat panel displays have been developed. The types of flat panel displays now include liquid crystal display (LCD), field emission display (FED), organic light emitting diode (OLED) and plasma display panel (PDP).

Organic light emitting diode (OLED) is sometimes referred to as organic electroluminescence display (OELD). OLED is a type of self-illuminating device arranged to form a matrix of points. Each OLED is driven by a low DC current to produce light having a high luminance and contrast. The OLED also has a high operating efficiency and carries very little weight. Moreover, the OLED may emit light within a range of colors including the three primary colors red (R), green (G), blue (B) and white light. Consequently, OLED is currently the most actively developed type of flat panel display. Aside from high-resolution, lightweight, active illumination, quick response and energy saving capacity, advantages of OLED further include a large viewing angle, good color contrast and low production cost. Currently, the OLED has many applications such as a light source at the back of a LCD or indicator panel in a mobile phone, a digital camera, a personal digital assistant (PDA) and so on.

According to the driving method, OLED may be classified into two major types, namely, a passive matrix driven type and an active matrix driven type. The passive matrix driven type OLED has a simpler structure and does not use any thin film transistor (TFT). Hence, the passive matrix driven OLED is easier and less expensive to produce. However, the passive matrix driven OLED has a lower resolution and consumes a lot of electrical energy if the display area is large. On the other hand, the active matrix driven OLED is suitable for fabricating large display panels. The active matrix driven OLED panel has a wide viewing angle, illuminates brightly and responds quickly to control signals. Nevertheless, the active matrix driven OLED panel is slightly more expensive to produce.

According to the driving mode, flat panel displays can be categorized as voltage driven or current driven. The voltage driven mode is commonly employed in a thin film transistor liquid crystal display (TFT-LCD). To operate a voltage driven TFT-LCD, different voltages are fed to data lines so that different color gray scales are produced. The voltage driven TFT-LCD is relatively stable and cheap to manufacture. The OLED is a type of current driven display. To operate an OLED display, different currents are fed to data lines so that different color gray scales are produced. Before operating this type of current driven pixel, however, new circuits and ICs must first be developed. The cost of developing new circuits and ICs is high. On the other hand, some technical problems are encountered if the voltage-driven circuit of a TFT-LCD is used to drive the OLED. Since the OLED characteristics for red (R), green (G) and blue (B) are different, different data voltages must be provided to produce a suitable R, G, B luminance ratio in the OLED for reproducing white light. Yet, the production of different output voltage data from a single IC is intrinsically difficult.

### SUMMARY OF INVENTION

Accordingly, one object of the present invention is to provide a driving circuit design for a display device that employs the voltage-driven circuit of a thin film transistor liquid crystal display (TFT-LCD). The pixel outputs a different driving current to each organic light emitting diode (OLED) having a characteristic red (R), green (G) or blue (B) coloration under identical data voltage condition. The driving current is varied by adjusting channel width/length ratio of the driver TFT of each pixel. Consequently, an appropriate luminance ratio between red, green and blue lights may be selected to reproduce white light through the red, green and blue OLED so that a full coloration is obtained.

To achieve these and other advantages and in accordance with the purpose of the invention, as embodied and broadly described herein, the invention provides a driving circuit design for a display device. The display device includes a plurality of pixels each having a driving thin film transistor (TFT) and an organic light emitting diode (OLED). Major aspects of the design method include identical data voltage input for each pixel and modification of the driving current produced by adjusting the channel width/length ratio of the driving thin film transistor (TFT). Ultimately, red, green and blue light emitted from the red, green and blue OLED at a definite luminance ratio may combine to produce white light and hence a full coloration.

In the embodiment of this invention, the driving current is the current passing through the drain terminal and the gate terminal of a driving TFT. Furthermore, luminance of red light may vary according to the structure and material of the red organic light emitting diode (red OLED). Similarly, luminance of green light and luminance of blue light may vary according to the structure and material of the green organic light emitting diode (green OLED) and the blue organic light emitting diode (blue OLED) respectively.

Luminance of red light is directly proportional to the emission efficiency of red light and driving current through unit area of the red OLED. Similarly, luminance of green light is directly proportional to the emission efficiency of green light and driving current through unit area of the green OLED and luminance of blue light is directly proportional to the emission efficiency of blue light and driving current through unit area of the blue OLED.

The source terminal of a driving TFT is coupled to the positive terminal of an OLED. The drain terminal of a driving TFT is coupled to a power source at a first voltage. The negative terminal of the OLED is coupled to another power source at a second voltage.

Each pixel further includes a thin film transistor (TFT) switch and a capacitor. The TFT switch has a drain terminal, a gate terminal and a source terminal. The drain terminal of the TFT switch is coupled to a driving IC. The gate terminal of the TFT switch is coupled to a scanning voltage. The source terminal of the TFT switch is coupled to the gate terminal of the driving TFT. The capacitor has a first and a second terminal. The first terminal of the capacitor is coupled to the source terminal of the TFT switch and the gate terminal of the driving TFT. The second terminal of the capacitor is coupled to a power source at a third voltage (Vref).

In brief, this invention uses the voltage-driven circuit of a conventional TFT-LCD such that the pixel is capable of outputting a different driving current to each OLED having a characteristic red, green or blue coloration under identical data voltage condition. Different driving currents are produced by adjusting channel width/length ratio of the TFT driver in each pixel. Consequently, an appropriate luminance ratio between red, green and blue lights may be set to reproduce white light through the red, green and blue OLED and hence attain full coloration.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram showing an equivalent driving circuit for a pixel inside a device designed according to one preferred embodiment of this invention;

FIG. 2 is a graph showing the relationship between emission efficiency and luminance for red, green and blue OLED; and

FIG. 3 is a graph showing the relationship between luminance and driving current for red, green and blue OLED.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

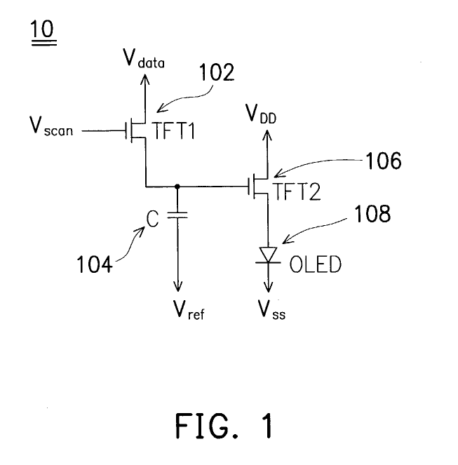

FIG. 1 is a diagram showing an equivalent driving circuit for a pixel inside a device designed according to one preferred embodiment of this invention. As shown in FIG. 1, each pixel 10 includes a thin film transistor switch (TFT1) 102, a capacitor 104, a driving thin film transistor (TFT2) 106 and an organic light emitting diode (OLED) 108. The OLED 108 is an actively driven matrix.

The thin film transistor switch (TFT1) 102 has a drain terminal, a gate terminal and a source terminal. The capacitor (C) 104 has a first terminal and a second terminal. The driving thin film transistor (TFT2) 106 has a drain terminal, a gate terminal and a source terminal. The organic light emitting diode 108 has a positive electrode and a negative electrode. The drain terminal of thin film transistor switch (TFT1) 102 is coupled to a data voltage. The gate terminal of the thin film transistor switch (TFT1) 102 is coupled to a scanning voltage. The source terminal of the thin film transistor switch (TFT1) 102 is coupled to the first terminal of the capacitor (C) 104 and the gate terminal of the driving thin film transistor (TFT2) 106. The second terminal of the capacitor (C) 104 is coupled to a power supplier at a reference voltage V_{ref}. The drain terminal of the driving thin film transistor (TFT2) 106 is coupled to a power supplier at a voltage V_{DD} The negative terminal of the organic light emitting diode (OLED) 108 is coupled to a power supplier at a voltage V_{SS}. In addition, the data voltage and the supply voltage (V_{DD}) are provided by a voltage source.

The following is a description of the operation of the pixel circuit. When the scanning voltage is at a high voltage level, voltage (V_{gs1}) between the gate terminal and the source terminal of the thin film transistor switch (TFT1) 102 is greater than a threshold voltage. Hence, the thin film transistor switch (TFT1) 102 conducts and the data voltage charges up the capacitor (C) 104. When the capacitor (C) 104 is charged up to a voltage equal to the voltage (V_{gs2}) between the gate terminal and source terminal of the driving thin film transistor (TFT2) 106, the driving thin film transistor (TFT2) 106 conducts. This leads to a driving current flowing between the drain terminal and the source terminal. The driving current flows through the organic light emitting diode (OLED) 108 to light up the device.

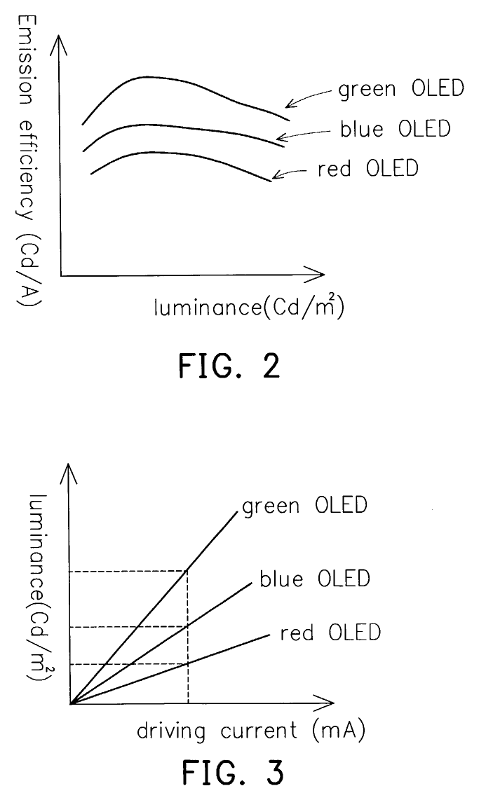

FIG. 2 is a graph showing the relationship between emission efficiency (EF) (units in candela/ampere, Cd/A) and luminance (units in candela/square meter, Cd/m²) for red (R), green (G) and blue (B) organic light emitting diode (OLED). As shown in FIG. 2, the emission efficiency and luminance for red OLED, green OLED and blue OLED are all different. Furthermore, luminance of the red, green and blue OLED may differ according to the structural layout and the material used. In general, luminance of an OLED is the product of the emission efficiency, the driving current passing through unit area of the OLED and a constant. FIG. 3 is a graph showing the relationship between luminance and driving current for red (R), green (G) and blue (B) OLED. As shown in FIG. 3, green OLED emits the highest luminance, blue OLED emits the second highest luminance and the red OLED emits the lowest luminance when subjected to an identical driving current.

Accordingly, red, green and blue OLED all have slightly different characteristic properties under an identical data voltage. Hence, driving current to red, green and blue OLED must be adjusted according to a selected luminance ratio before white light is produced. Drain current Id produced by a thin film transistor (TFT) at the saturation region follows a formula: I_{d}=(½)×μₙ×Cₒₓ×(W/L)×(V_{gs}−Vₜₕ)², where electron mobility μₙ and gate capacitance for unit area Cₒₓ has a constant value, Vₜₕ is threshold voltage of the thin film transistor (TFT), W is channel width of the thin film transistor (TFT) and L is the length of the thin film transistor (TFT). Since voltages between the gate terminal and source terminal of the driving thin film transistor for driving the red, green and blue OLED are identical (that is, V_{gsR}=V_{gsG}=V_{gsB}), the driving thin film transistor (TFT) can be set to produce different driving current for driving each type of color OLED by changing the width/length (W/L) ratio of the driving thin film transistor (TFT). Ultimately, red, green and blue OLED emit light having a suitable mix of luminance ratio to produce white light and hence attain full coloration. For example, assume the emission efficiency (EF) for red, green and blue OLED are: EF_{R}=2(Cd/A), EF_{G}=10(Cd/A), EF_{B}=2(Cd/A) and the required luminance ratio for producing white light is: B_{R}:B_{G}:B_{B}=3:6:1. Current flowing through unit area of the OLED I_{d}=(½)×μₙ×Cₒₓ×(W/L)×(V_{gs}−Vₜₕ)²=K₁×(W/L)×(V_{gs}−Vₜₕ), where K₁=(½)×μₙ×Cₒₓ is a constant and V_{gsR} =V_{gsG}=V_{gsB}. According to the luminance formula, B=L₂×EF×I_{d} (where K₂ is a constant), the width/length (W/L) ratio of the driving thin film transistor (TFT) for driving red, green and blue OLED is found as follows:

$$\begin{matrix}\begin{matrix}{B}_{R} : {B}_{G} : {B}_{B} = 3 : 6 : 1 = {k}_{1} \times {k}_{2} \times E {F}_{R} \times {( W \text{/} L )}_{R} \times {( {V}_{g s R} {V}_{t h} )}^{2} : {k}_{1} \times {k}_{2} \times E {F}_{G} \times \\ {( W \text{/} L )}_{G} \times {( {V}_{g s G} {V}_{t h} )}^{2} : {k}_{1} \times {k}_{2} \times E {F}_{B} \times {( W \text{/} L )}_{B} \times {( {V}_{g s B} {V}_{t h} )}^{2} = E {F}_{R} \times \end{matrix} \\ {( W \text{/} L )}_{R} : E {F}_{G} \times {( W \text{/} L )}_{G} : E {F}_{B} \times {( W \text{/} L )}_{B} = 2 \times {( W \text{/} L )}_{R} : 10 \times {( W \text{/} L )}_{G} : 2 \times {( W \text{/} L )}_{B}\end{matrix}$$

Hence, (W/L)_{R}:(W/L)_{G}:(W/L)_{B}=15:6:5. Using this width/length (W/L) ratio, different driving currents are produced and fed to red, green and blue OLED respectively. With this mix of luminance ratio, white light is produced so that full coloration is possible.

In summary, this invention uses the voltage-driven circuit of a conventional TFT-LCD such that the pixel is capable of outputting a different driving current to each OLED having a characteristic red, green or blue coloration under identical data voltage conditions. Different driving currents are produced by adjusting channel width/length ratio of the TFT driver in each pixel. Consequently, an appropriate luminance ratio between red, green and blue lights may be set to reproduce white light through the red, green and blue OLED and hence attain full coloration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A driving circuit design for a display device having a plurality of pixels with each pixel including a driving thin film transistor and an organic light emitting diode, the design comprising:
each pixel receiving an identical data voltage; and
modifying the driving current generated by the driving thin film transistor through the adjustment of the width/length ratio of the driving thin film transistor so that the luminance of red light emitted from a red organic light emitting diode, the luminance of green light emitted from a green organic light emitting diode and the luminance of blue light emitted from a blue light emitting diode are in such a ratio that white light is produced and full coloration is attained.

2. The driving circuit design of claim 1, wherein the driving current passes between the drain terminal and the gate terminal of the driving thin film transistor.

3. The driving circuit design of claim 1, wherein the luminance of red light emitted by an organic light emitting diode depends on the structure and material forming the organic light emitting diode.

4. The driving circuit design of claim 1, wherein the luminance of green light emitted by an organic light emitting diode depends on the structure and material forming the organic light emitting diode.

5. The driving circuit design of claim 1, wherein the luminance of blue light emitted by an organic light emitting diode depends on the structure and material forming the organic light emitting diode.

6. The driving circuit design of claim 1, wherein the luminance and emission efficiency of red light is proportional to the driving current flowing across unit area of the red organic light emitting diode.

7. The driving circuit design of claim 1, wherein the luminance and emission efficiency of green light is proportional to the driving current flowing across area of the green organic light emitting diode.

8. The driving circuit design of claim 1, wherein the luminance and emission efficiency of blue light is proportional to the driving current flowing across unit area of the blue organic light emitting diode.

9. The driving circuit design of claim 1, wherein the source terminal of the driving thin film transistor is coupled to the positive terminal of the organic light emitting diode.

10. The driving circuit design of claim 1, wherein the drain terminal of the driving thin film transistor is coupled to a power supply at a first voltage level.

11. The driving circuit design of claim 1, wherein the negative terminal of the organic light emitting diode is coupled to a power supply at a second voltage level.

12. The driving circuit design of claim 1, wherein each pixel further includes:
a thin film transistor switch having a drain terminal, a gate terminal and a source terminal, wherein the drain terminal is coupled to the data voltage, the gate terminal is coupled to a scanning voltage and the source terminal is coupled to the gate terminal of the driving thin film transistor; and
a capacitor having a first terminal and a second terminal, wherein the first terminal is coupled to the source terminal and the gate terminal of the driving thin film transistor, and the second terminal is coupled to a power supply at a third voltage level.
